(19) United States
(12) Patent Application Publication
(10) Pub. No.: US 2025/0179685 A1
(43) Pub. Date: Jun. 5, 2025

(54) SILICON CARBIDE PLATFORMS AND THE MANUFACTURE THEREOF THROUGH SILICON CARBIDE EPITAXY ON SILICON

(71) Applicant: HEWLETT PACKARD ENTERPRISE DEVELOPMENT LP, Spring, TX (US)

(72) Inventor: Sagi Varghese Mathai, Sunnyvale, CA (US)

(21) Appl. No.: 18/526,700

(22) Filed: Dec. 1, 2023

(51) Int. Cl. C30B 25/04; C30B 25/18; C30B 29/36; H01L 21/02; H01L 21/78

(52) U.S. Cl. CPC C30B 25/04; C30B 25/18; C30B 29/36; H01L 21/02381; H01L 21/02488; H01L 21/02529; H01L 21/02538; H01L 21/02645; H01L 21/02647; H01L 21/7806

(57) ABSTRACT

A method of manufacturing a silicon-carbide platform comprises providing a base comprising a silicon seed layer having a (001) crystal lattice plane and a top surface parallel to the (001) crystal lattice plane and forming a silicon-carbide epitaxial layer by epitaxial growth directly on the top surface of the silicon seed layer. A silicon-on-insulator substrate may be used to form the silicon-carbide platform in some implementations. The silicon-carbide epitaxial layer may be grown by epitaxial lateral overgrowth over a mask layer in some implementations. The silicon-carbide platform may comprise additional layers, such as a Ill-V semiconductor layer disposed on and bonded to the silicon-carbide epitaxial layer in some implementations. The silicon-carbide epitaxial layer may be buried between two other layers in some implementations.

### INTRODUCTION

Silicon carbide (SiC) can be used to form a variety of semiconductor devices, including SiC-based electronic devices, optoelectronic devices, photonic integrated circuits, and micro-electromechanical systems (MEMS). The demand for such SiC-based devices is increasing in recent years. In particular, the demand for SiC-based power devices, such as power transistors (e.g., MOSFETs), is increasing due, in part, to increased demand for electrical vehicles and renewable energy.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a schematic cross-section of an example SiC platform.

FIG. 2 is a schematic cross-section of an example SiC-on-SOI platform.

FIG. 3 is a schematic cross-section of the SiC-on-SOI platform of FIG. 2 in a first stage of manufacture.

FIG. 4 is a schematic cross-section of the SiC-on-SOI platform of FIG. 2 in a second stage of manufacture.

FIG. 5 is a schematic cross-section of the SiC-on-SOI platform of FIG. 2 in a third stage of manufacture.

FIG. 6 is a schematic cross-section of an example SiC-ELOG platform.

FIG. 7 is a schematic cross-section of the SiC-ELOG platform of FIG. 6 in a first stage of manufacture.

FIG. 8 is a schematic cross-section of the SiC-ELOG platform of FIG. 6 in a second stage of manufacture.

FIG. 9 is a schematic cross-section of the SiC-ELOG platform of FIG. 6 in a third stage of manufacture.

FIG. 10 is a schematic cross-section of the SiC-ELOG platform of FIG. 6 in a fourth stage of manufacture.

FIG. 11 is a schematic cross-section of the SiC-ELOG platform of FIG. 6 in a fifth stage of manufacture.

FIG. 12 is a schematic cross-section of the SiC-ELOG platform of FIG. 6 in a sixth stage of manufacture.

FIG. 13 is a schematic cross-section of an example SiC-III-V platform.

FIG. 14 is a schematic cross-section of a first portion of the SiC-III-V platform of FIG. 13 in a first stage of manufacture.

FIG. 15 is a schematic cross-section of a first portion of the SiC-III-V platform of FIG. 13 in a second stage of manufacture.

FIG. 16 is a schematic cross-section of a second portion of the SiC-III-V platform of FIG. 13 in a third stage of manufacture.

FIG. 17 is a schematic cross-section of the SiC-III-V platform of FIG. 13 in a fourth stage of manufacture.

FIG. 18 is a schematic cross-section of the SiC-III-V platform of FIG. 13 in a fifth stage of manufacture.

FIG. 19 is a schematic cross-section of the SiC-III-V platform of FIG. 13 in a sixth stage of manufacture.

FIG. 20 is a schematic cross-section of an example buried-SiC platform.

FIG. 21 is a schematic cross-section of a first portion of the buried-SiC platform of FIG. 20 in a first stage of manufacture according to a first method of manufacture.

FIG. 22 is a schematic cross-section of the first portion of the buried-SiC platform of FIG. 20 in a second stage of manufacture according to the first method of manufacture.

FIG. 23 is a schematic cross-section of a second portion of the buried-SiC platform of FIG. 20 in a third stage of manufacture according to the first method of manufacture.

FIG. 24 is a schematic cross-section of the buried-SiC platform of FIG. 20 in a fourth stage of manufacture according to the first method of manufacture.

FIG. 25 is a schematic cross-section of the buried-SiC platform of FIG. 20 in a fifth stage of manufacture according to the first method of manufacture.

FIG. 26 is a schematic cross-section of the buried-SiC platform of FIG. 20 in a sixth stage of manufacture according to the first method of manufacture.

FIG. 27 is a schematic cross-section of a first portion of the buried-SiC platform of FIG. 20 in a first stage of manufacture according to a second method of manufacture.

FIG. 28 is a schematic cross-section of a second portion of the buried-SiC platform of FIG. 20 in a second stage of manufacture according to the second method of manufacture.

FIG. 29 is a schematic cross-section of the buried-SiC platform of FIG. 20 in a third stage of manufacture according to the second method of manufacture.

FIG. 30 is a schematic cross-section of the buried-SiC platform of FIG. 20 in a fourth stage of manufacture according to the second method of manufacture.

FIG. 31 is a schematic cross-section of the buried-SiC platform of FIG. 20 in a fifth stage of manufacture according to the second method of manufacture.

FIG. 32 is a schematic cross-section of an example III-V-on-SiC-ELOG platform.

FIG. 33 is a schematic cross-section of a first portion of the III-V-on-SiC-ELOG platform of FIG. 32 in a first stage of manufacture.

FIG. 34 is a schematic cross-section of a second portion of the III-V-on-SiC-ELOG platform of FIG. 32 in a second stage of manufacture.

FIG. 35 is a schematic cross-section of the III-V-on-SiC-ELOG platform of FIG. 32 in a third stage of manufacture.

FIG. 36 is a schematic cross-section of the III-V-on-SiC-ELOG platform of FIG. 32 in a fourth stage of manufacture.

FIG. 37 is a schematic cross-section of the III-V-on-SiC-ELOG platform of FIG. 32 in a fifth stage of manufacture.

### DETAILED DESCRIPTION

As noted above, demand for SiC semiconductor devices is increasing. However, SiC wafers can be difficult and costly to produce by existing techniques. Many techniques for SiC wafer production result in low die production volume, due to a limited maximum wafer size (and thus a limited number of dies per wafer) and/or due to relatively long per-wafer production times. For example, it can take around 5-10 days to form a SiC boule, as compared to about 8 hours to form a Si boule. In addition, due to its hardness, SiC boules are more difficult to slice and polish into wafers than Si boules. Furthermore, in many approaches to SiC wafer production, the wafers tend to be limited in size to a maximum of about 150 mm (using some manufacturing techniques) or 200 mm (using some manufacturing techniques), and the wafers tend to be very expensive (compared to similarly sized Si wafers). Thus, to support the expected increase in demand for SiC devices, techniques for producing SiC platforms that have higher die production volume (e.g., larger wafer size and/or less time per wafer) and lower production costs are needed.

To address these and other issues, examples disclosed herein include various SiC platforms and techniques for manufacturing the same which have relatively high production volumes and relatively low production costs. The SiC platforms each comprise multiple stacked material layers including at least a Si seed layer and a SiC epitaxial layer which is formed by epitaxy on the Si seed layer. More specifically, in some examples the Si seed layer comprises a (001) Si crystal lattice plane, and the SiC epitaxial layer grows (at least initially) from the (001) Si crystal lattice plane. Thus, the SiC epitaxial layer has a corresponding crystal orientation as the (001) Si seed layer. In various of the example platforms, one or more other layers (in addition to the Si seed layer and SiC epitaxial layer) may also be present, such as an oxide layer, a III-V semiconductor layer, or other layers as will explained in greater detail below. The Si seed layer may be provided in the form of a bare Si wafer or in the form of an exposed Si layer of some other substrate, such as a silicon device layer of a silicon-on-insulator (SOI) substrate.

The SiC platforms disclosed herein, which use Si as the seed layer for epitaxial growth, can be larger than platforms formed by SiC epitaxy on a SiC seed layer, because the Si seed layers used in examples disclosed herein (e.g., Si wafers, SOI substrates, etc.) tend to be available at larger maximum sizes than SiC wafers/substrates. For example, Si wafers or SOI substrates are commonly available up to 300 mm diameter (with 450 mm projected), whereas SiC wafers tend to be limited to 150 mm or 200 mm diameters (depending on the process used to form them). This difference in size can make a substantial difference for die production volume—for example, a 200 mm wafer may be processed into 269 dies (each at 100 mm²) whereas a 300 mm wafer may be processed into 640 dies (each at 100 mm²), which is about a 2.4× increase. In addition, the formation of SiC platforms disclosed herein can be less costly than, for example forming platforms by SiC epitaxy on a SiC seed layer, because Si substrates tend to be less expensive than SiC substrates. Moreover, formation of the SiC platforms through SiC epitaxy on Si seed layers can be much faster, easier, and cheaper than attempting to grow SiC boules and slice them into wafers. Thus, example SiC platforms disclosed herein may be produced at higher productions volumes and lower costs than would be possible with other approaches to producing SiC wafers.

Turning now to the figures, various devices, systems, and methods in accordance with aspects of the present disclosure will be described.

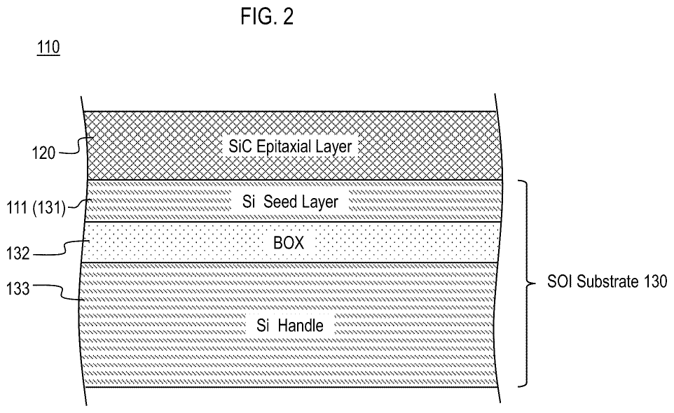

FIGS. 2-37 schematically illustrate various SiC platforms in cross-section. These figures are schematic in nature and not intended to illustrate specific dimensions or other structural details accurately or to scale, unless otherwise noted.

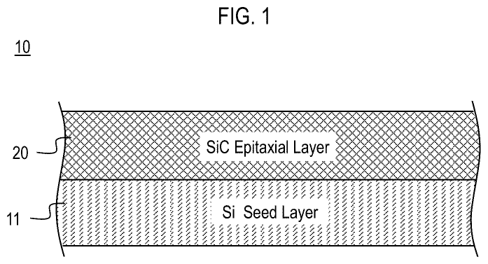

Turning now to FIG. 1, a SiC platform 10 will be described. As shown in FIG. 1, the SiC platform 10 comprises at least two material layers: a Si seed layer 11 and a SiC epitaxial layer 20 formed on the Si seed layer 11.

The Si seed layer 11 may be provided as a standalone Si substrate (e.g., a Si wafer) or as an exposed layer of some other substrate such as an SOI substrate. The Si seed layer 11 may comprise Si with a crystal structure orientated such that the surface upon which the SiC epitaxial layer 20 grows (the top surface in FIG. 1) corresponds to (i.e., is parallel to) the (001) crystal lattice plane of the Si seed layer 11. Si wafers, SOI substrates, or other substrates having a Si layer with such a crystal orientation are widely commercially available.

The SiC epitaxial layer 20 may be grown via epitaxy on the Si seed layer 11, specifically on the surface which is parallel to the (001) crystal lattice plane (this surface is referred to herein as the “top” surface out of convenience, but this does not limit the orientation of the SiC platform 10 relative to an eternal reference frame such as the ground). Various techniques for epitaxy are known in the art, such as chemical vapor deposition (CVD), physical vapor deposition (PVD), molecular beam epitaxy (MBE), chemical beam epitaxy (CBE), atomic layer epitaxy (ALE), and liquid phase epitaxy (LPE), and any such epitaxy technique may be used to form the SiC epitaxial layer 20. Because one of ordinary skill in the art would be familiar with epitaxy techniques, they are not described in greater detail herein.

The SiC epitaxial layer 20 may have a cubic crystal structure like the Si upon which it is grown. Moreover, because the SiC epitaxial layer 20 is grown on the surface corresponding to the (001) lattice plane of the Si seed layer 11, the SiC epitaxial layer 20 may have a similar crystal orientation as the Si seed layer 11 (e.g., a (001) crystal lattice plane of the SiC layer 20 may be parallel to the (001) crystal lattice plane of the Si seed layer 11). In addition, the SiC epitaxial layer comprises the 3C-SiC polytype. Many existing SiC devices (semiconductor devices, photonic devices, etc.) are formed from 4H-SiC or 6H-SiC polytypes, but generally the 3C-SiC polytype may have material properties that are also suitable for use in forming similar SiC devices. In some examples, the SiC epitaxial layer 20 may be in-situ doped during growth. In other examples, the SiC epitaxial layer 20 may be undoped (high resistivity or semi-insulating).

In some examples, the SiC platform 10 can be used to create a variety of electronic, optical, or electrooptical devices on or in layers of the platform 10 through various known techniques, such as photolithography, etching, deposition (e.g., thin film deposition), implantation (e.g., ion-implantation), thermal oxidation, etc. More specifically, in some examples, the SiC platform 10 comprises, or may be processed to form, various devices, such as electronic devices, optoelectronic devices, photonic components or photonic integrated circuits, and micro-electromechanical systems (MEMS). In some examples, such devices are formed by processing the SiC platform 10 subsequent to the platform 10 being manufactured, similar to how a Si wafer, SOI substrate, or SiC wafer may be processed to form various devices. In other examples, devices may be formed, in part or in whole, during the manufacture of the SiC platform 10 without necessarily requiring subsequent processing to form the device. In some examples, devices are formed at least in part in or on the SiC epitaxial layer. In some examples, devices are formed in other layers (described in greater detail below).

In some examples, the SiC platform 10 may comprise a wafer-like structure, similar to a Si wafer or SOI substrate. In some examples, the Si seed layer 11 may have a wafer diameter of 200 mm, and therefore the SiC layer 20 and the SiC platform 10 as a whole may also have a wafer diameter of 200 mm. In some examples, the Si seed layer 11 may have a wafer diameter greater than 200 mm, such as 300 mm or 450 mm, and therefore the SiC layer 20 and the SiC platform 10 as a whole may also have a wafer diameter greater than 200 mm (e.g., 300 mm, 450 mm, etc.). In some examples, the SiC platform 10 may comprise a die which has been cut from a larger wafer. In some examples, the SiC platform 10 may comprise a semiconductor device, integrated circuit, and/or photonic integrated circuit, in which case the SiC platform 10 may comprise various devices and circuits formed in or on the layers 11 and 20 (or in/on other layers of the SiC platform 10, which are not illustrated in FIG. 1).

Although only two material layers are shown in FIG. 1, the SiC platform 10 may comprise one or more additional layers in various configurations. For example, FIGS. 2, 6, 13, 20, and 32 illustrate a number of SiC platforms which are specific configuration examples of the SiC platform 10 in which additional material layers are present and/or which have been formed by various different methods. These example configurations of the SiC platform 10 will be described in greater detail below. Some components of the various SiC platforms correspond to (i.e., are the same as, similar to, or example implementations of) components of the SiC platform 10 already described above; such corresponding components are identified by use of similar reference numbers which have the same last two digits (e.g., 120 and 220). The descriptions herein of one component in relation to one example SiC platform are applicable to any corresponding components in any of the other SiC platforms unless noted otherwise or logically contradictory, and duplicative descriptions of corresponding components may be omitted.

Turning to FIG. 2, a first example configuration of the SiC platform 10 will be described, in the form of SiC platform 110. The SiC platform 110 may also be referred to as a SiC-on-SOI platform 110, because it comprises a SiC layer 120 formed on an SOI substrate 130. In some examples, the SOI substrate 130 comprises a first Si layer 133 (also referred to herein as the Si handle 133), a buried oxide (BOX) layer 132 on the Si handle 133, and a second Si layer 131 (also referred to herein as the Si device layer 131) on the BOX layer 132. This is one type of commercially available SOI substrate. In some examples, the Si device layer 131 is less than 50 nm thick and a top surface thereof is aligned with the (001) crystal lattice plane. In some examples, the BOX layer 132 is 0.1-10 μm thick. In some examples, the BOX layer 132 comprises silicon dioxide (SiO2).

Furthermore, the SiC epitaxial layer 120 is grown by epitaxy on the Si device layer 131 of the SOI substrate 130. In other words, the Si device layer 131 is used as the seed layer for the SiC growth (i.e., the Si device layer 131 is one implementation example of the seed layer 11), and thus the Si device layer 131 may also be referred to herein as the Si seed layer 111 or Si seed/device layer 111, 131. The SiC epitaxial layer 120 is one implementation example of the SiC epitaxial layer 20. In some examples, the SiC epitaxial layer 120 is about 0.05 μm to 10 μm thick. With the addition of the SiC epitaxial layer 120 to the SOI substrate 130, the SiC-on-SOI platform 110 is formed and has at least the following layers, in order from bottom to top: Si handle 133, BOX layer 132, Si seed/device layer 111, 131, and SiC epitaxial layer 120.

In some examples, the SiC-on-SOI platform 110 may be particularly suitable for use in forming photonic integrated circuits. For example, the SiC/Si layers 111/120 with appropriate patterning may form the core of an optical waveguide. The BOX layer 132 may serve as the lower cladding, while an SiO2 layer (not shown) grown on top of the SiC layer 120 may serve as the upper cladding.

The configuration of the SOI substrate 130 shown in FIG. 2 is merely one example SOI configuration, and in various examples of the platform 110 a different type of SOI substrate may be used instead. Specifically, an SOI substrate comprises at least a Si device layer disposed on an insulator. In FIG. 2, the insulator happens to be the BOX layer 132 disposed on the Si handle 133. But in other examples, the Si device layer 131 may be disposed on a different insulator, such as a sapphire substrate (not illustrated) or some other insulator. In addition, in some examples, the Si handle 133 may be omitted. Regardless of the type of SOI substrate that is used, in each example of the platform 110 the SOI substrate has a Si device layer 131 and the SiC epitaxial layer 120 is epitaxially grown on the Si device layer 131.

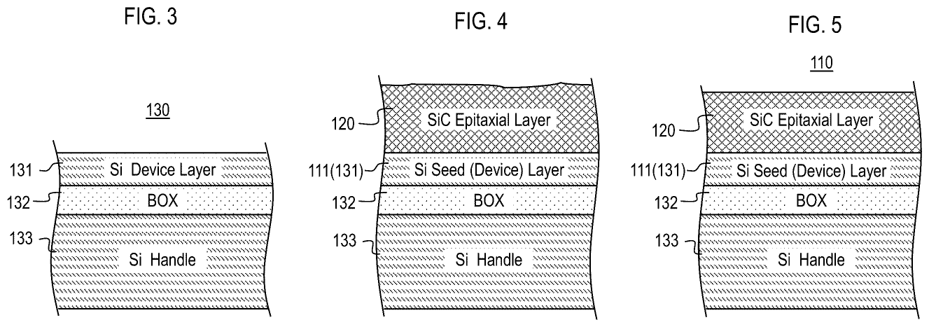

Turning to FIGS. 3-5, a method of manufacturing the SiC-on-SOI platform 110 will be described. First, as shown in FIG. 3, an SOI substrate 130 is provided. In FIG. 3, it is assumed that the SOI substrate 130 comprises a Si handle 133, BOX layer 132, and Si device layer 131. However, any type of SOI substrate may be provided in this stage, as explained above. Providing the SOI substrate 130 comprises obtaining possession and/or control over the SOI substrate 130, which may include, for example, manufacturing the SOI substrate 130, purchasing the SOI substrate 130, etc.

Next, as shown in FIG. 4, the SiC epitaxial layer 120 is grown by epitaxy on the top surface of the Si seed/device layer 111, 131. Specifically, in some examples, the SiC epitaxial layer 120 comprises a 3C-SiC polytype epitaxially grown directly on the (001) surface of the Si seed/device layer 111, 131. In some examples, no thick buffer layers are needed for the growth of the SiC epitaxial layer 120.

Next, as shown in FIG. 5, in some examples, the top surface of the SiC epitaxial layer 120 may be polished or smoothened by various known techniques, such as chemical-mechanical polishing (CMP), reactive ion etching (RIE), atomic layer etching (ALE), or combinations thereof. In some cases, epitaxial growth can result in a top surface which may be rough. In some applications, the level of roughness may be acceptable, in which case the polishing step can be omitted. However, in some applications, a smoother surface may be desired, in which case the polishing step can be performed. In particular, in various photonics applications in which a photonic device is formed on or in the platform 110, a low roughness surface for the SiC epitaxial layer 120 can improve the optical loss for the photonic device.

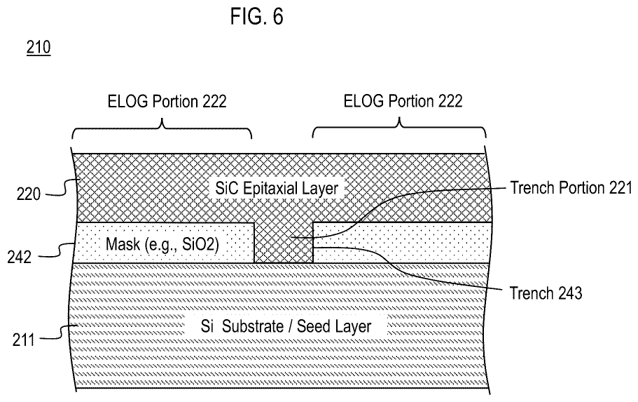

Turning to FIG. 6, a second example configuration of the SiC platform 10 will be described, in the form of SiC platform 210. The SiC platform 210 may also be referred to as a SiC-ELOG platform 210 because, in this example, the SiC epitaxial layer 220 is formed by epitaxial lateral overgrowth (ELOG), which will be described in greater detail below. The SiC-ELOG platform 210 comprises a Si substrate 211, a mask 242 formed on the Si substrate 211, and a SiC epitaxial layer 220 which is formed on the Si substrate 211 and extends laterally over the mask 242.

The SiC epitaxial layer 220 is grown by epitaxy on the Si substrate 211. In other words, the Si substrate 211 is used as the seed layer for the SiC growth (i.e., the Si substrate 211 is one implementation example of the seed layer 11), and thus the Si substrate 211 may also be referred to herein as the Si seed layer 211 or Si substrate/seed layer 211. The thickness of the Si substrate is not limited, although in some examples it may be desired to have the Si substrate be at least thick enough to provide a desired level of physical support for the platform 210.

The mask 242 is formed on a top layer of the Si substrate 211, which corresponds to the (001) crystal lattice plane of the Si substrate 211. The mask 242 may comprise silicon dioxide (SiO2), for example. The mask 242 has one or more trenches 243 or other openings formed therein such that portions of the top layer of the substrate 211 are exposed from above. The term “trenches” is used herein for simplicity, but it should be understood that the trenches 243 could have a variety of shapes, including but not limited to a narrow-elongated trench/groove/channel shape, a round or rectangular hole or well shape, a hole with irregular perimeter, or any desired shape. Moreover, although the trench 243 is shown as having side walls which are disposed at 90 degrees (perpendicular) relative to the top surface of the of the Si substrate 211, the angles between the side walls and the top surface, which are denoted α and β in FIG. 8, may be other than 90 degrees. For example, in some implementations the angles α and β between the side walls and the top surface of the Si substrate 211 may be between 10 and 170 degrees, and may include positively sloped sidewalls or negatively sloped (undercut) side walls. Moreover, the slope of one side wall need not be the same as the slope of the other side wall (i.e., the angles α and β do not necessarily have to be equal). In some examples, the mask layer is about 0.05 μm to 10 μm thick

The SiC epitaxial layer 220 begins its growth in the trenches 243 on the Si substrate/seed layer 211, growing to fill the trenches 243 and laterally overgrow the mask 242. Thus, the SiC epitaxial layer 220 comprises a trench portion 221 which is disposed within the trench 243 in contact with a top surface of the Si substrate/seed layer 211 and ELOG portions 222 which extend laterally over the mask 242 and face/abut a top surface of the mask 242. The SiC epitaxial layer 220 is one implementation example of the SiC epitaxial layer 20. In some examples, the SiC epitaxial layer 220 is about 0.05 μm to 10 μm thick.

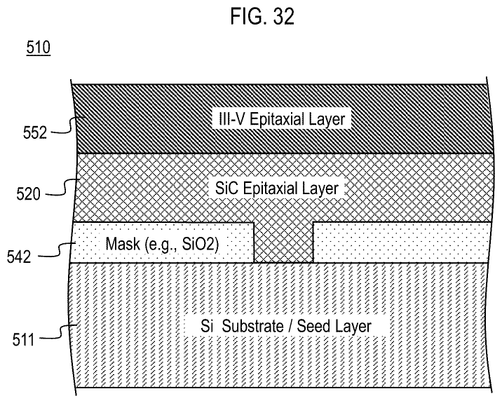

In some examples, the SiC-ELOG platform 210 may be used to form MEMS systems, such as MEMS sensors & actuators, in which case, the SiC layer may serve as the MEMS structural layer and the SiO2 mask may serve as the sacrificial release layer. In some examples, the SiC-ELOG platform 210 may be used to form quantum SiC color center integrated circuits. SiC color centers may be formed by intentionally creating defects, such as Si vacancies, in the SiC layer. In some examples, the SiC-ELOG platform 210 may be used as a building block to form additional SiC platforms, such as the SiC platform 510 described below in relation to FIG. 32.

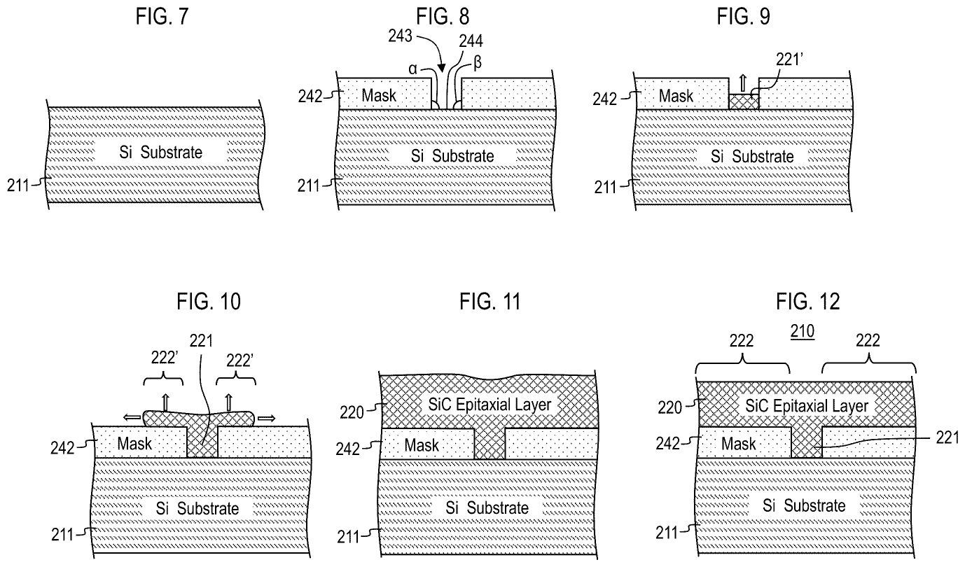

Turning to FIGS. 7-12, a method of manufacturing the SiC-ELOG platform 210 will be described. For simplicity, the description of the method will focus on a single trench 243, but it should be understood that the same descriptions apply to each individual trench 243 if multiple are present. First, as shown in FIG. 7, a silicon substrate 211 is provided. The silicon substrate 211 may be, for example, a Si wafer with its top surface corresponding to the (001) crystal lattice plane.

Next, as shown in FIG. 8, the mask 242 is formed on the Si substrate 211. The mask 242 may be formed in a variety of ways which would be familiar to those of ordinary skill in the art, such as growth of a thin film followed by wet or dry etching to form the one or more trenches 243 therein and expose portions 244 of the top surface of the Si substrate 211 within the trenches 243.

Next, as shown in FIG. 9, SiC epitaxial growth begins in the trench 243 on the exposed portions 244 of the Si substrate/seed layer 211. FIG. 9 illustrates an initial portion of the epitaxial growth process in which just a part 221′ of the trench portion 221 has been formed in the trench 243. During this stage of SiC epitaxial growth, the SiC grows primarily upward, as indicated by the arrow in FIG. 9. Moreover, because the epitaxial growth begins on the (001) surface of the Si substrate 211, the trench portion 221 of the SiC epitaxial layer 220 has a similar crystal orientation as the Si substrate 211 (i.e., an (001) lattice plane of the SiC epitaxial layer 220 may be parallel to the (001) lattice plane of the Si substrate 211).

As the epitaxial growth process continues, eventually, the SiC reaches the top of the trench 243 (i.e., the trench portion 221 fills the trench 243), whereupon the SiC epitaxial layer 220 begins to grow laterally outward over the mask 242, in addition to continuing to also grow upward, as shown by the arrows in FIG. 10. FIG. 10 shows an intermediate stage in the epitaxial growth process in which parts 222′ of the ELOG portions 222 have been formed and extend partially over the mask 242. As the epitaxial growth process continues, eventually the ELOG portions 222 of the SiC epitaxial layer 220 will grow laterally to extend over the mask 242 until a desired extent of overgrowth is achieved, as shown in FIG. 11, whereupon the epitaxial growth process may be discontinued. In some cases, the ELOG portion 222 of the SiC epitaxial layer 220 extend fully over the entirety of the mask 242. As the ELOG portions 222 grow laterally from the trench portion 221, they maintain the same crystal orientation as the trench portion 221, which has the same crystal orientation as the Si substrate 211. Thus, although the ELOG portions 222 do not directly abut or grow directly from the Si substrate 211, they maintain the same crystal orientation as the Si substrate 211 due to their formation through ELOG from the trench portion 221 which is grown directly from the (001) surface of the substrate 211.

Next, as shown in FIG. 12, in some examples, the top surface of the SiC epitaxial layer 220 may be planarized or smoothed by various known techniques, such as chemical-mechanical polishing (CMP), reactive ion etching (RIE), atomic layer etching (ALE), or combinations thereof. In particular, not only is it possible for the top surface of the SiC epitaxial layer 220 to be somewhat rough due to the normal variations occurring in epitaxy, in the example of FIG. 12 the top surface of the SiC epitaxial layer 220 may also have noticeable differences in height at the boundaries between trench portions 221 and ELOG portions 222 specifically due to the growth pattern of the epitaxial layer 220 in the ELOG process. Thus, in platforms 210 intended for use in applications which benefit from smooth surfaces, such as photonics applications, the planarization step may be performed. In platforms 210 intended for use in applications which do not require smooth surfaces, such as some MEMS applications, the planarization step may be omitted.

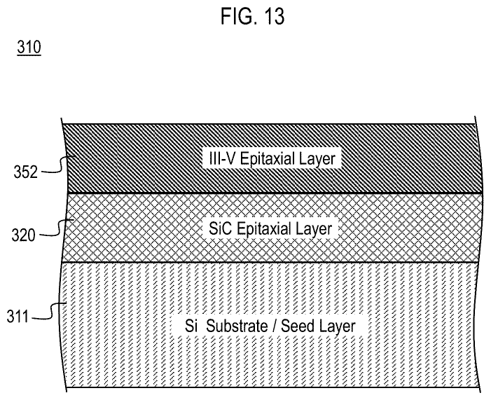

Turning to FIG. 13, a third example configuration of the SiC platform 10 will be described, in the form of SiC platform 310. The SiC platform 310 may also be referred to as a SiC-III-V platform 310 because, in this example, a III-V semiconductor layer 352 is disposed on the SiC epitaxial layer 320. The SiC-III-V platform 310 comprises a Si substrate 311, a SiC epitaxial layer 320 which is formed on the Si substrate 311, and the III-V semiconductor layer 352 is disposed on the SiC epitaxial layer 320.

The III-V semiconductor layer 352 may comprise any compound semiconductor comprising one or more elements from group 13 of the periodic table (formerly known as group III; also known as the Boron group) and one or more elements from group 15 of the periodic table (formerly known as group V; also known as the Nitrogen group). In some examples, the III-V semiconductor layer 352 is about 0.05 μm to 20 μm thick.

The SiC epitaxy layer 352 is grown by epitaxy from the substrate 311, and thus the Si substrate 311 is one example implementation of the seed layer 11. Accordingly, the Si substrate 311 may also be referred to herein as the Si substrate/seed layer 311. In some examples, the SiC epitaxial layer 320 is about 0.05 μm to 10 μm thick. The Si substrate/seed layer 311 may comprise a standard Si wafer having an (001) lattice plane parallel to the top surface thereof. The thickness of the Si substrate 311 is not limited herein.

In some examples, the SiC-III-V platform 310 may be used to form high power III-V electronic and optoelectronic devices. In some examples, the SiC epitaxial layer 320 can function as the lower cladding in III-V optical waveguides formed in the III-V layer 352 due to the low refractive index of the SiC layer 320.

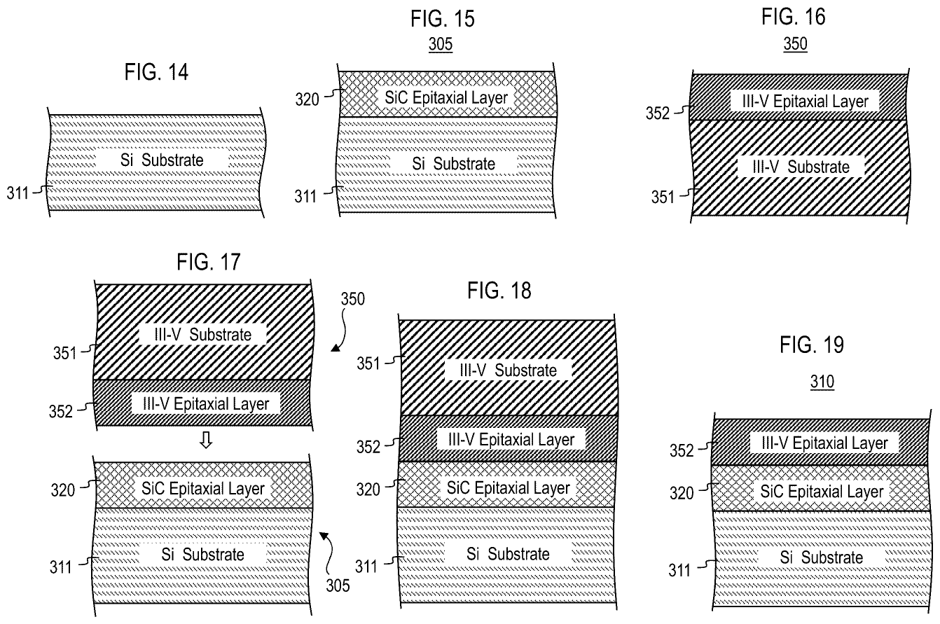

Turning to FIGS. 14-19, a method of manufacturing the SiC-III-V platform 310 will be described. First, as shown in FIG. 14, a silicon substrate 311 is provided. The silicon substrate 311 may be, for example, a Si wafer with its top surface corresponding to the (001) crystal lattice plane.

Next, as shown in FIG. 15, the SiC epitaxial layer 320 is grown by epitaxy on the top surface of the Si substrate/seed layer 311. This results in the formation of a first intermediate platform 305.

Prior to, subsequent to, or concurrently with the production of the first intermediate platform 305, a second intermediate platform 350 is provided, as shown in FIG. 16. The second intermediate platform 350 comprises a III-V substrate 351 and a III-V epitaxial layer 352 formed by epitaxy on the III-V substrate 351. In some examples, the III-V epitaxial layer 352 and the III-V substrate 351 may comprise the same III-V semiconductor, but the III-V epitaxial layer 352 may have a different doping type and concentration than the III-V substrate 351. In other examples, the III-V substrate 351 may comprise a different III-V semiconductor material than the III-V epitaxial layer 352. In some examples, the III-V epitaxial layer 352 may consist of a single layer or multiple layers of III-V semiconductors. In some examples, providing the second intermediate platform 350 comprises forming the second intermediate platform 350 by growing the III-V epitaxial layer 352 on the III-V substrate 351 by techniques that would be familiar to those of ordinary skill in the art. In other examples providing the second intermediate platform 350 comprises purchasing or otherwise obtaining possession and/or control over an already formed second intermediate platform 350.

Once the first and second intermediate platforms 305 and 350 have both been provided, they may be bonded together, as shown in FIGS. 17-18. More specifically, the first and second intermediate platforms 305 and 350 are positioned such that the III-V epitaxial layer 352 and the SiC epitaxial layer 320 face one another, as shown in FIG. 17, and then they may be moved together such that these layers 352 and 320 touch, as shown in FIG. 18. The touching surfaces of these layers 352 and 320 may be directly bonded to one another without any intervening layer, for example by oxide interfacial layer free bonding or by any other bonding method. Although not illustrated, in some examples the SiC epitaxial layer 320 and/or the III-V epitaxial layer 352 may be polished/smoothed prior to or as part of the bonding process to facilitate better bonding.

In FIGS. 17-18, the second intermediate platform 350 is shown as being inverted (flipped over) and disposed on top of the first intermediate platform 305 for the bonding, but in other examples the first intermediate platform 305 may be inverted and disposed on the top of the second intermediate platform 350 for bonding. In other words, the orientations of the intermediate platforms 305 and 350 relative to the ground or some other external reference frame during the bonding are not limited herein, instead, only their orientation relative to one another during the bonding are limited as shown and described.

Next, as shown in FIG. 19, the III-V substrate layer 351 can be removed. This reveals what is now the top surface of the III-V epitaxial layer 352 (which was previously the bottom surface thereof in the orientation of FIG. 16). The remaining layers 311, 320, and 352 form the Si-III-V platform 310. The III-V substrate layer 351 can be removed by grinding, CMP, wet or dry etching, or combinations thereof.

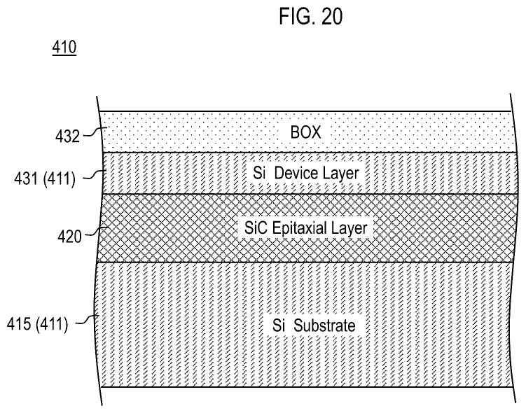

Turning to FIG. 20, a fourth example configuration of the SiC platform 10 will be described, in the form of SiC platform 410. The SiC platform 410 may also be referred to as a buried-SiC platform 410 because, in this example, the SiC epitaxial layer 420 is buried (i.e., disposed between two other layers). The buried-SiC platform 410 comprises a Si substrate 415, a SiC epitaxial layer 420 layered on the Si substrate 415, a Si device layer 431 layered on the SiC epitaxial layer 420, and a BOX layer 432 disposed on the Si device layer 431.

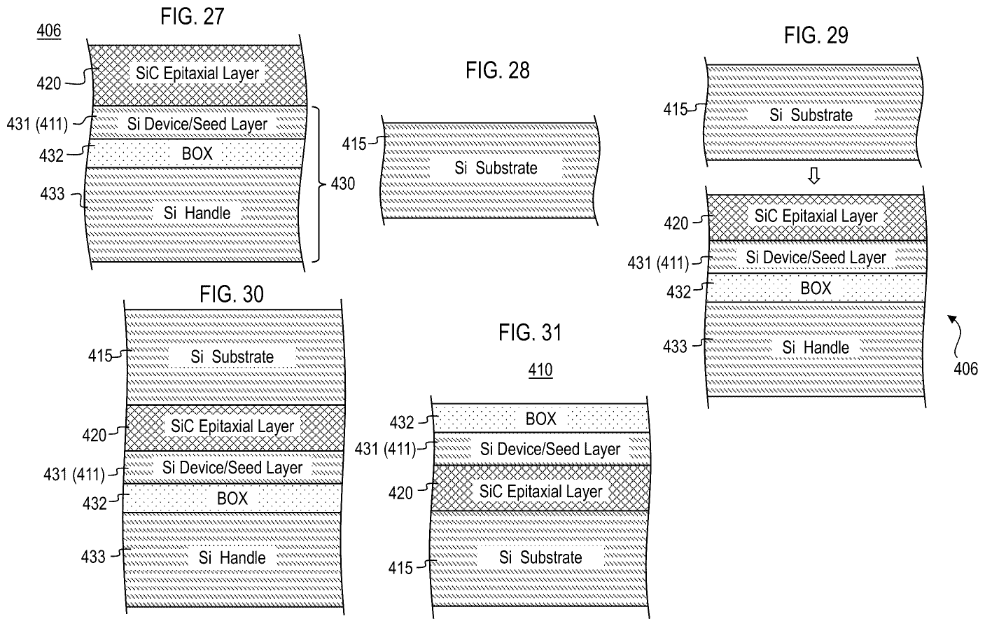

In some examples, the Si device layer 431 and BOX layer 432 may originally be part of an SOI substrate 430 (see FIGS. 23 and 27) which is used to form the platform 410. In some examples, the SOI substrate 430 may be similar to the SOI substrate 130 described above. As described in greater detail below, a handle 433 of the SOI substrate 430 may be removed during manufacture of the platform 410, and thus the handle 433 does not appear in FIG. 20.

The SiC epitaxial layer 420 is formed by epitaxy on a Si seed layer 411, wherein the seed layer 411 is either the Si substrate 415 or Si device layer 431, depending on the implementation of the buried-SiC platform 410. More specifically, in some implementations of the buried-SiC platform 410, the SiC epitaxial layer 420 is formed by epitaxy on the Si substrate 415, in which case the Si substrate 415 is the seed layer 411 and may be referred to as the Si substrate/seed layer 415, 411. In other implementations of the buried-SiC platform 410, the SiC epitaxial layer 420 is formed by epitaxy on the Si device layer 431, in which case the Si device layer 431 is the seed layer 411 and may be referred to as the Si device/seed layer 431, 411. The Si substrate 415 as the seed layer 411 is one implementation example of the seed layer 11, and similarly the Si device layer 431 as the seed layer 411 is another implementation example of the seed layer 11. In some examples, the SiC epitaxial layer 420 is about 0.05 μm to 10 μm thick.

In some examples, the BOX layer 432 may be used as an etch mask for subsequent patterning of the Si device layer 431 by dry or wet etching, e.g., to form devices in the Si device layer 431 and/or SiC epitaxial layer 420.

In some examples, the buried-SiC platform 410 may be used to form active and passive photonic integrated circuits (PICs) much like PICs formed on SOI wafers. The SiC epitaxial layer performs the same function as the BOX layer in SOI wafers to implement PICs. Additionally, the SiC layer has a much higher thermal conductivity than the BOX layer, and therefore, can more efficiently spread heat away from active photonic devices such as lasers, modulators and photodetectors.

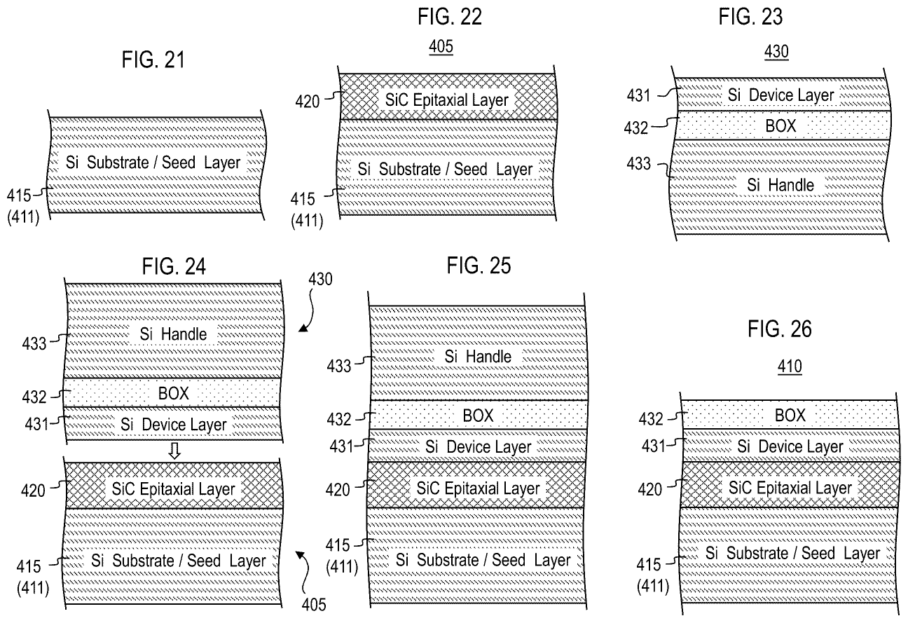

Turning to FIGS. 21-26, a first method of manufacturing the buried-SiC platform 410 will be described. First, as shown in FIG. 21, a silicon substrate 415 is provided. The silicon substrate 415 may be, for example, a Si wafer with its top surface corresponding to the (001) crystal lattice plane.

Next, as shown in FIG. 22, the SiC epitaxial layer 420 is grown by epitaxy from the top surface of the Si-substrate 415. Thus, in this method, the Si substrate 415 acts as the seed layer 411. The result is a first intermediate platform 405.

Prior to, subsequent to, or concurrently with the formation of the first intermediate platform 405, an SOI substrate 430 is provided, as shown in FIG. 430. The SOI substrate 430 may be similar to the SOI substrate 130 described above, and may comprise a Si handle 433, BOX layer 432, and Si device layer 431.

Once the first intermediate platform 405 and SOI substrate 430 have both been provided, they may be bonded together, as shown in FIGS. 24-25. More specifically, the first intermediate platform 405 and the SOI substrate 430 are positioned such that the Si device layer 431 and the SiC epitaxial layer 420 face one another, as shown in FIG. 24, and then they may be moved together such that these layers 431 and 420 touch, as shown in FIG. 25. The touching surfaces of these layers 431 and 420 may be directly bonded to one another without any intervening layer, for example by oxide interfacial layer free bonding or by any other bonding method. In this manner, the SiC epitaxial layer 420 becomes buried between the Si device layer 431 and the Si substrate 415. Although not illustrated, in some examples the SiC epitaxial layer 420 and/or the Si device layer 431 may be polished/smoothed prior to or as part of the bonding process to facilitate better bonding.

In FIGS. 24-25, the SOI substrate 430 is shown as being inverted (flipped over) and disposed on top of the first intermediate platform 405 for the bonding, but in other examples the first intermediate platform 405 may be inverted and disposed on the top of the SOI substrate 430 for bonding. In other words, the orientations of the intermediate platform 405 and SOI substrate 430 relative to the ground or some other external reference frame during the bonding are not limited herein, instead, only their orientation relative to one another during the bonding are limited as shown and described.

Next, as shown in FIG. 26, the Si handle 433 can be removed. This reveals what is now the top surface of the BOX layer 432 (which was the bottom surface thereof in the orientation of FIG. 23). The remaining layers 415 (411), 420, 431, and 432 form the buried-SiC platform 410. The Si handle layer 433 can be removed by grinding, CMP, plasma etching, or combinations thereof. The BOX (e.g., SiO2) layer 432 may serve as an etch stop for CMP and plasma etching to remove the Si handle 433. The BOX layer 432 may also be referred to herein as an oxide layer after the Si handle 433 has been removed, as in this state the layer is no longer buried.

Turning to FIGS. 27-31, a second method of manufacturing the buried-SiC platform 410 will be described. First, as shown in FIG. 27, a SiC-on-SOI platform 406 is provided. The SiC-on-SOI platform 406 corresponds to the SiC-on-SOI platform 110 described above, and comprises an SOI substrate 430 (comprising a Si handle 433, a BOX layer 432, an SOI substrate) and a SiC epitaxial layer 420 formed by epitaxial growth on the SOI substrate 430 (specifically, on the Si device layer 431). Thus, in this method of manufacturing the buried-SiC platform 410, the Si device layer 431 acts as the seed layer 411.

Prior to, subsequent to, or concurrently with the provisioning of the SiC-on-SOI platform 406, a Si-substrate 415 is provided, as shown in FIG. 28. The silicon substrate 415 may be, for example, a Si wafer.

Once the SiC-on-SOI platform 406 and Si substrate 415 have both been provided, they may be bonded together, as shown in FIGS. 29-30. More specifically, the SiC-on-SOI platform 406 and the Si substrate 415 are positioned such that the Si substrate 415 and the SiC epitaxial layer 420 face one another, as shown in FIG. 29, and then they may be moved together such that these layers 415 and 420 touch, as shown in FIG. 30. The touching surfaces of these layers 415 and 420 may be directly bonded to one another without any intervening layer, for example by oxide interfacial layer free bonding or by any other bonding method. In this manner, the SiC epitaxial layer 420 becomes buried between the Si device layer 431 and the Si substrate 415. Although not illustrated, in some examples the SiC epitaxial layer 420 and/or the Si substrate 415 may be polished/smoothed prior to or as part of the bonding process to facilitate better bonding.

In FIGS. 29-30, the Si substrate 415 is shown as being disposed on top of the SiC-on-SOI platform 406 for the bonding, but in other examples the SiC-on-SOI platform 406 may be inverted and disposed on the top of the Si substrate 415 for bonding. In other words, the orientations of the SiC-on-SOI platform 406 and Si substrate 415 relative to the ground or some other external reference frame during the bonding are not limited herein, instead, only their orientation relative to one another during the bonding are limited as shown and described.

Next, as shown in FIG. 31, the Si handle 433 can be removed. This reveals what is now the top surface of the BOX layer 432 (which was the bottom surface thereof in the orientation of FIG. 29). The remaining layers 415, 420, 431 (411), and 432 form the buried-SiC platform 410. The Si handle layer 433 can be removed by grinding, CMP, plasma etching, or combinations thereof. The BOX (e.g., SiO2) layer 432 may serve as an etch stop for CMP and plasma etching to remove the Si handle 433.

Turning to FIG. 32, a fifth example configuration of the SiC platform 10 will be described, in the form of SiC platform 510. The SiC platform 510 may also be referred to as a III-V-on-SiC-ELOG platform 510 because, in this example, a III-V layer 552 is disposed on the SiC epitaxially layer 520 comprising ELOG portions. In other words, the III-V-on-SiC-ELOG platform 510 comprises a modified version of the SiC-ELOG platform 210 described above in which a III-V layer 552 has been disposed on and bonded to the SiC epitaxial layer of the SiC-ELOG platform 210. More specifically, the SiC-ELOG platform 210 comprises a Si substrate/seed layer 511, a mask 542 formed on the Si substrate/seed layer 511 with a trench formed therein, a SiC epitaxial layer 520 formed by ELOG from the Si substrate/seed layer 511 (via the trench) and laterally extending over the mask 542, and a III-V epitaxial layer 552 disposed on the SiC epitaxial layer 520. In this example, the Si substrate/seed layer 511 is one configuration of the seed layer 11.

In some examples, the III-V-on-SiC-ELOG platform 510 may be used to form high power lasers, modulators and photodetectors.

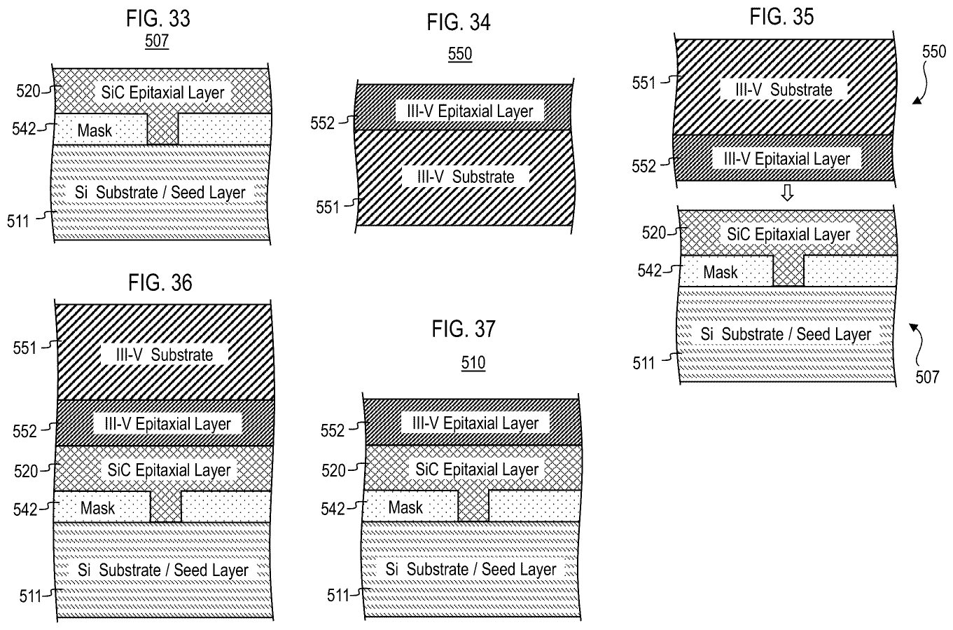

Turning to FIGS. 33-37, a method of manufacturing the III-V-on-SiC-ELOG platform 510 will be described. First, as shown in FIG. 33, a SiC-ELOG platform 507 may be provided. The SiC-ELOG platform 507 corresponds to the SiC-ELOG platform 210 described above, and comprises a Si substrate/seed layer 511, a mask 542 formed on the Si substrate/seed layer 511 with a trench formed therein, and a SiC epitaxial layer 520 formed by ELOG from the Si substrate/seed layer 511 (via the trench) and laterally extending over the mask 542.

Prior to, subsequent to, or concurrently with the provisioning of the SiC-ELOG platform 507, a III-V intermediate platform 550 is provided, as shown in FIG. 34. The Ill-V intermediate platform 550 is similar to the second intermediate platform 350 described above, and may comprise a III-V substrate 551 and a III-V epitaxial layer 552 formed by epitaxy on the III-V substrate 551.

Once the SiC-ELOG platform 507 and III-V intermediate platform 550 have both been provided, they may be bonded together, as shown in FIGS. 35-36. More specifically, the SiC-ELOG platform 507 and III-V intermediate platform 550 are positioned such that the III-V epitaxial layer 552 and the SiC epitaxial layer 520 face one another, as shown in FIG. 35, and then they may be moved together such that these layers 552 and 520 touch, as shown in FIG. 36. The touching surfaces of these layers 552 and 520 may be directly bonded to one another without any intervening layer, for example by oxide interfacial layer free bonding or by any other bonding method. Although not illustrated, in some examples the SiC epitaxial layer 520 and/or the III-V epitaxial layer 552 may be polished/smoothed prior to or as part of the bonding process to facilitate better bonding.

In FIGS. 35-36, the III-V intermediate platform 550 is shown as being inverted and disposed on top of the SiC-ELOG platform 507 for the bonding, but in other examples the SiC-ELOG platform 507 may be inverted and disposed on the top of the III-V intermediate platform 550 for bonding. In other words, the orientations of the SiC-ELOG platform 507 and III-V intermediate platform 550 relative to the ground or some other external reference frame during the bonding are not limited herein, instead, only their orientation relative to one another during the bonding are limited as shown and described.

Next, as shown in FIG. 37, the III-V substrate 551 can be removed. This reveals what is now the top surface of the III-V epitaxial layer 552 (which was the bottom surface thereof in the orientation of FIG. 34). The remaining layers 511, 542, 520, and 552 form the III-V-SiC-ELOG platform 510. The III-V substrate 551 can be removed by grinding, CMP, wet or dry etching, or combinations thereof.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A method of manufacturing a silicon-carbide platform, comprising:
providing a base comprising a silicon seed layer having a (001) crystal lattice plane and a top surface parallel to the (001) crystal lattice plane; and
forming a silicon-carbide epitaxial layer by epitaxial growth directly on the top surface of the silicon seed layer.

2. The method of claim 1,
wherein the base comprises a silicon-on-insulator (SOI) substrate comprising a first silicon substrate, a buried oxide (BOX) layer, and silicon device layer, and
wherein the silicon seed layer comprises the silicon device layer of the SOI substrate.

3. The method of claim 2, further comprising:
forming an electronic device, optical device, optoelectronic device, integrated circuit, and/or photonic integrated circuit, at least in part, in the silicon-carbide epitaxial layer and/or in the silicon device layer.

4. The method of claim 2, further comprising:
providing a second silicon substrate;
bonding the second silicon substrate to the silicon-carbide epitaxial layer; and
removing the first silicon substrate to expose the BOX layer.

5. The method of claim 4, further comprising:
forming an electronic device, optical device, optoelectronic device, integrated circuit, and/or photonic integrated circuit, at least in part, in the silicon-carbide epitaxial layer and/or in the silicon device layer.

6. The method of claim 1,
wherein the base comprises a silicon substrate and a mask formed on the silicon substrate;
wherein the silicon seed layer comprises the silicon substrate;
wherein one or more trenches are formed in the mask to expose portions of a top surface of the silicon substrate; and
wherein forming the silicon-carbide epitaxial layer on the silicon seed layer by epitaxial growth comprises:
epitaxially growing silicon carbide on the exposed portions of the top surface of the silicon substrate in the one or more trenches; and
causing the silicon carbide to extend laterally from the one or more trenches over the mask by epitaxial lateral overgrowth to form the silicon-carbide epitaxial layer with one or more portions of the silicon-carbide epitaxial layer being disposed on the mask.

7. The method of claim 6,
wherein the mask comprises a silicon dioxide layer.

8. The method of claim 6, further comprising:
forming an electronic device, optical device, optoelectronic device, integrated circuit, photonic integrated circuit, and/or micro-electromechanical system, at least in part, in the silicon-carbide epitaxial layer.

9. The method of claim 6, further comprising:
providing a III-V platform comprising a III-V substrate and a III-V epitaxial layer on the III-V substrate;
bonding the III-V epitaxial layer to the silicon-carbide epitaxial layer; and
removing the III-V substrate to expose the III-V epitaxial layer.

10. The method of claim 9, further comprising:
planarizing the silicon-carbide epitaxial layer prior to bonding the III-V epitaxial layer to the silicon-carbide epitaxial layer.

11. The method of claim 9, further comprising:
forming an electronic device, optical device, optoelectronic device, integrated circuit, photonic integrated circuit, and/or micro-electromechanical system, at least in part, in the silicon-carbide epitaxial layer and/or in the III-V epitaxial layer.

12. The method of claim 1,
wherein the base comprises a silicon substrate;
wherein the silicon seed layer comprises the silicon substrate; and
wherein the method further comprises:
providing a III-V platform comprising a III-V substrate and a III-V epitaxial layer;
bonding the III-V epitaxial layer to the silicon-carbide epitaxial layer; and
removing the III-V substrate to expose the III-V epitaxial layer.

13. The method of claim 12, further comprising:
forming an electronic device, optical device, optoelectronic device, integrated circuit, and/or photonic integrated circuit, at least in part, in the silicon-carbide epitaxial layer and/or in the III-V epitaxial layer.

14. The method of claim 1, further comprising:
providing a silicon-on-insulator (SOI) substrate comprising a first silicon substrate, buried oxide (BOX) layer, and silicon device layer,
wherein the base comprises a second silicon substrate and the silicon seed layer comprises the second silicon substrate; and
wherein the method further comprises:
bonding the silicon device layer to the silicon-carbide epitaxial layer; and
removing the first silicon substrate to expose the BOX layer.

15. The method of claim 14, further comprising:
forming an electronic device, optical device, optoelectronic device, integrated circuit, and/or photonic integrated circuit, at least in part, in the silicon-carbide epitaxial layer and/or in the Si device layer.

16. A silicon-carbide platform, comprising:
a base comprising a silicon seed layer having a (001) crystal lattice plane and a top surface parallel to the (001) crystal lattice plane; and
a silicon-carbide epitaxial layer formed by epitaxial growth directly on the top surface of the silicon seed layer.

17. The silicon-carbide platform of claim 16,
wherein the base comprises a silicon-on-insulator (SOI) substrate comprising a first silicon substrate, a buried oxide (BOX) layer on the first silicon substrate, and a silicon device layer on the BOX layer, and
wherein the silicon seed layer comprises the silicon device layer of the SOI substrate.

18. The silicon-carbide platform of claim 16, further comprising:
wherein the base comprises a silicon substrate, the silicon-carbide epitaxial layer on the silicon substrate, a silicon device layer on the silicon-carbide epitaxial layer, and an oxide layer on the silicon device layer, and
wherein the silicon seed layer comprises the silicon device layer.

19. The silicon-carbide platform of claim 16, further comprising:
wherein the base comprises a silicon substrate, the silicon-carbide epitaxial layer on the silicon substrate, a silicon device layer on the silicon-carbide epitaxial layer, and an oxide layer on the silicon device layer, and
wherein the silicon seed layer comprises the silicon substrate.

20. The silicon-carbide platform of claim 16,
wherein the base comprises a silicon substrate and a mask formed on the silicon substrate;
wherein the silicon seed layer comprises the silicon substrate;
wherein one or more trenches are formed in the mask to expose portions of a top surface of the silicon substrate; and
wherein the silicon-carbide epitaxial layer comprises:
a trench portion disposed on and epitaxially grown from the exposed portions of the top surface of the silicon substrate in the one or more trenches; and
one or more portions disposed on the mask and grown by epitaxial lateral overgrowth from the trench portions.
